(19) United States
(12) Patent Application Publication
(10) Pub. No.: US 2004/0003638 A1
(43) Pub. Date: Jan. 8, 2004

(54) Transfer of holographic images into metal sporting and fitness products

(76) Inventors: Mark W. Schaefer, Knoxville, TN (US); Thomas L. Levendusky, Greensburg, PA (US); Simon Sheu, Murrysville, PA (US); Robert B. Larsen, Maryville, TN (US); Neville C. Whittle, Pittsburgh, PA (US)

Correspondence Address: ALCOA INC, ALCOA TECHNICAL CENTER, 100 TECHNICAL DRIVE, ALCOA CENTER, PA, 15069-0001, US

(21) Appl. No.: 10/430,593

(22) Filed: May 6, 2003

Related U.S. Application Data
(63) Continuation-in-part of application No. 09/473,246, filed on Dec. 27, 1999.
Application No. 09/473,246 is a continuation-in-part of application No. 09/166,974, filed on Oct. 6, 1998, now Pat. No. 6,006,415.
Application No. 09/166,974 is a continuation-in-part of application No. 08/991,101, filed on Dec. 12, 1997, now Pat. No. 5,881,444.

(51) Int. Cl. B21B 45/02; B21D 22/00; B21B 39/20; G03H 1/04; G03F 7/16; G03F 7/20; G03F 7/40; B05D 1/00; C23C 16/26; C25D 1/10; C23C 14/22; C23C 14/34

(52) U.S. Cl. 72/41; 72/85; 72/252.5; 430/1; 430/320; 430/323; 430/324; 427/133; 427/249.7; 205/70; 204/192.11; 204/192.38

(57) ABSTRACT

A method for impressing holographic images or holograms in the surface of sporting and fitness products such as ball bats and bicycle frames. The surfaces of metal shims and print rolls bearing holograms are hardened as by coating them with thin amorphous diamond coatings or diamond like coatings so the holograms can be embossed into many thousands of metal objects with clarity and consistency.

### CROSS-REFERENCE TO RELATED APPLICATIONS

This is a continuation-in-part of U.S. patent application Ser. No. 09/473,246, filed Dec. 27, 1999, which was a continuation-in-part of U.S. patent application Ser. No. 09/166,974, filed Oct. 6, 1998, now U.S. Pat. No. 6,006,415, which was a continuation-in-part of U.S. patent application Ser. No. 08/991,101, filed Dec. 12, 1997, now U.S. Pat. No. 5,881,444.

### BACKGROUND OF THE INVENTION

1. Field of the Invention

This invention relates to pressing or microengraving holograms and/or diffraction images into metallic surfaces of sporting and fitness products such as ball bats, bicycle frames, sports rackets and exercise equipment.

2. Description of the Prior Art

Many recreational and competitive softball and baseball players prefer to use ball bats made of hard temper aluminum alloys. There are two predominant methods for decorating baseball and softball bats: powder coating and anodizing. Both processes utilize silk screening as the primary method of applying decorative images and corporate logos to the painted or anodized aluminum. There is a need for improved and enhanced technology for decoration of ball bats to improve their appeal.

There is also a need for improved techniques for manufacturers to authenticate their ball bats to help prevent counterfeiting of these products. One way that manufacturers authenticate/identify their products is by applying an adhesive label, sometimes including holograms on the labels, that indicate that the bats were made in their plants. These labels tend to fade and peel off the bats over time, and are usually placed in areas on the bats that take much abuse. The labels also can be expensive. Improved identification/authentication technology is needed which would withstand abuse and be more durable.

It is well known to manufacture a variety of products having holograms or diffraction images pressed or embossed into them. Such products include credit cards, license plates, consumer packaging, pictures, tickets and the like. See, for example, U.S. Pat. Nos. 4,368,979; 4,684,795; 4,856,857; 4,971,646; 4,999,075; and 5,267,753. Holograms generally mean a diffraction pattern which produces a three-dimensional image. Other diffraction images modify the behavior of light that strikes an object bearing the image without creating a three-dimensional appearance. The term “hologram” is used herein in the broad sense to include diffraction patterns or images as well as three-dimensional holograms and other complex images having different planes of diffraction. The manufacture of holograms, shims or plates is well known in the art as disclosed in U.S. Pat. Nos. 3,733,258; 3,875,026; 3,944,420; and 5,059,499, among others.

Most holograms on credit cards and the like are embossed into a plastic sheet material such as Mylar® or other polyester which has a thin underlayer of reflective material such as aluminum to produce a reflective hologram. The aluminum is typically vapor deposited onto the substrate. Holograms can also be impressed into thermoplastic layers on durable substrates as disclosed in U.S. Pat. No. 4,913,858. The coated sheet is heated to soften the coating which is decorated using an embossing member to provide a diffraction pattern or hologram.

It is further known to create embossing tools or roller dies bearing holographic patterns which are impressed into aluminum foil, translucent plastics and other materials, as is disclosed in U.S. Pat. No. 5,521,030. That patent discloses a process in which the holographic pattern is etched directly into a durable surface on the tool or die. The patent states that large quantities of holograms can be made from a single die made of high quality steel, chrome, or the like that is used in the roller die. The patent further states that the die may be a flat plate mounted on a substrate, an inside surface of an injection mold, a mandrel, a casting mold, or other surface used for transferring a relief pattern. The patent states that the holographic pattern may be embossed into aluminum foil, aluminum sheets, steel beverage containers, or the like.

It is also known to emboss holograms directly into the outer surface of sheet metal such as aluminum foil and aluminum beverage cans as is disclosed in U.S. Pat. Nos. 4,773,718 and 4,725,111. Those patents explain that the temperature of the aluminum is important for optimizing the embossing process and that the nickel master plate must be many times less deformable at the embossing temperature than is the material being embossed. The patents describe a process in which the aluminum foil and aluminum cans are heated to reduce the yield strength of the metal. The yield strength of the nickel master is relatively constant over the temperature range in which the yield strength of the aluminum in the foil and cans is dramatically reduced. The patents disclose embossing apparatus having a metal embossing plate carried on the outside surface of a wheel which is pressed against a can mounted on a mandrel. The embossing plate is heated by a heater that may be disposed within the wheel. The machine has a plurality of mandrels for cans which are sequentially embossed. The mandrels are preferably cooled. The process disclosed by these patents has not been used commercially despite the desirability of enhancing the decoration of cans.

Another technique for forming a hologram or diffraction grating in a metal blank or a metal container is disclosed in U.S. Pat. No. 5,193,014. According to that patent, a hologram or diffraction grating is first formed on a gently curved surface of a metal plate mold, followed by stamping the metal blank or can with the plate mold to transfer the hologram.

An improved low cost technique is desired for embossing holograms into metal sporting and fitness products such as ball bats, tubes for bicycle frames, rackets for tennis and the like, and exercise equipment. Many thousands of aluminum ball bats are made and sold annually, and improved decoration and authentication of such bats would improve their marketability. Aluminum sporting products are frequently made from hard temper aluminum alloys which provide high strength and durability for the products. It is important that the temper and strength of sporting products not be unduly reduced during processing as can happen if the sporting products are heated.

A technique for embossing or engraving holograms on sporting and fitness products is needed which adds little to the cost of the products and which produces consistently high quality images. It is desirable for a manufacturing system to be capable of engraving/embossing holograms on thousands of products in order to be commercially practicable. Sporting goods companies demand high quality and will not accept noticeable variations in the decoration on their products. The decoration processes must also be statistically in control and capable at such speeds.

### SUMMARY OF THE INVENTION

The present invention meets the above-described needs by providing a process for decorating and authenticating many thousands of high quality aluminum sporting and fitness products. The cost of decorating aluminum sporting and fitness products by this invention is nominal and is economical for mass marketing of the products. This invention can be used for decorating a variety of metal products such as ball bats, rackets for tennis and the like, tubes for bicycle frames, exercise equipment and the like.

This invention uses a nickel shim having a holographic pattern in it, which is used to manufacture multiple master dies for decorating metallic products. The master die may be in the form of a print roll into which the holographic pattern is transferred. The master die may also be a shim having sufficient surface hardness to transfer a holographic image to hard sheet metal. The master die is made of metal having a suitable hardness relative to the nickel shim in order to make a high quality transfer of the image from the shim to the master die. It is preferred that the nickel shim has a hardness which is at least about 2.5 times the hardness of the material at the surface of the master dies. If a nickel shim is used as a master die, the shim should have a hardness of at least about 2.5 times the hardness of the article to which the image is to be transferred.

Following transfer of the pattern from the shim to the master die or dies, the surface of the dies are hardened as for example by putting an amorphous diamond coating (ADC) or a diamond like coating (DLC) on them. The coating is very thin and of uniform thickness to minimize possible adverse effect on the clarity of the holographic pattern, while being thick enough to provide the requisite hardness for engraving/embossing many thousands of ball bats, tubes for bicycle frames or other sporting or fitness products.

It is an object of this invention to provide a method for engraving/embossing holograms into the exterior surface of hard metal sporting and fitness such as ball bats, tubes for bicycle frames, sports rackets and exercise equipment.

Another object of this invention is to provide a method for economically engraving/embossing holograms having uniformity and clarity into thousands of metal sporting products with the same dies.

It is also an object of this invention to provide improved dies for engraving/embossing holograms into sporting and fitness products made of hard metal.

A further object is to provide a method and apparatus for decorating sporting products with holograms and decorative coatings without adversely affecting the mechanical properties of the products.

Another object is to provide improved hologram-decorated sporting and fitness products made of hard temper aluminum.

Yet another object is to provide a method for producing print rolls having holographic images on them which are suitable for engraving/embossing thousands of hard metal articles such as aluminum ball bats or other aluminum sporting and fitness products.

The above and other objects and advantages of this invention will be more fully understood and appreciated with reference to the attached drawings and the following description of the invention.

### BRIEF DESCRIPTION OF THE DRAWINGS

FIG. 1 is a flow diagram showing the steps employed to decorate/emboss metal sporting and fitness products such as ball bats with holograms in accordance with this invention.

FIG. 2 is a cross-sectional view showing transfer of a hologram image from a shim to a print roll to be used to decorate/emboss bats in accordance with this invention.

FIG. 3 is a cross-sectional view showing apparatus for transferring/embossing of a hologram image from a print roll into the surface of an aluminum ball bat.

FIG. 4 is a side elevational view showing a decorator apparatus for impressing/embossing holograms into the surface of the barrel portion of a ball bat.

FIG. 5 is a fragmentary perspective view of a ball bat that has been decorated/embossed with a hologram in accordance with this invention.

FIG. 6 is a flow diagram showing the steps in an alternative mode for decorating/embossing sporting and fitness products with holograms.

FIG. 7 is a cross-sectional view showing an alternative apparatus and mode for practicing the invention.

### DESCRIPTION OF THE PREFERRED EMBODIMENTS

According to the present invention, metal ball bats, tubes for bicycle frames and other sporting and fitness products have holographic images or holograms impressed, microengraved or embossed in their surfaces by print rolls having the negative of the images impressed in their roll surfaces. The objects that are decorated/embossed in accordance with this invention are preferably made of hard temper aluminum alloys such as 7000 and 8000 series aluminum alloys. In the case of aluminum ball bats, the bats are made by a variety of techniques, such as swaging a cylindrical extrusion or tube as disclosed by U.S. Pat. No. 3,854,316, rolling a portion of an aluminum tube to reduce its diameter as disclosed by U.S. Pat. No. 5,125,251, or reforming an aluminum tube as disclosed by U.S. Pat. No. 5,626,050, the disclosure of which is incorporated herein by reference. Bats produced by such processing usually have a barrel portion, a handle section and a tapered section connecting the barrel section and handle section. The wall thicknesses of the three portions are different, with the thickness of the barrel portion typically being the same as the original thickness of the tube. The tapered portion and handle portion of the bat typically have thicker walls.

As used herein, the terms “engrave”, “emboss”, “transfer” and “impress” mean the transfer of a holographic or a diffraction image from one article or tool to another article or tool by pressing the articles or tools against one another under high pressure. The images are in the form of very small grooves or pits in or on the surface of the objects. The transfer is into the outer surface of the tools and articles.

Ball bats, sports rackets and aluminum tubes and extrusions for the manufacture of bicycle frames and the like, which are engraved/embossed in accordance with this invention, preferably have high specularity or brightness in order to produce the desired clarity of the hologram in the surface of the article. This means that the metal products preferably have a substantially mirror-like surface characterized by having a high distinctness of reflected image (“D/I” for brevity). When a ball bat or other product having a high D/I is positioned adjacent an article or an image or printing on paper or the like, the image or reflection on the bat or other metal product should be clear. D/I is the sharpness of the reflected image, and is preferably in a range of at least about 50 to 70% for products to be engraved/embossed by the method of this invention. High specularity can be produced on the bats, tubular metal and other products in a variety of ways such as burnishing or buffing the exterior surfaces of the bats and other products or by chemically cleaning and etching them. However, bat and tube makers may be able to produce products having specularity levels, after being washed, which may be high enough for transfer of holograms to the products without further brightening.

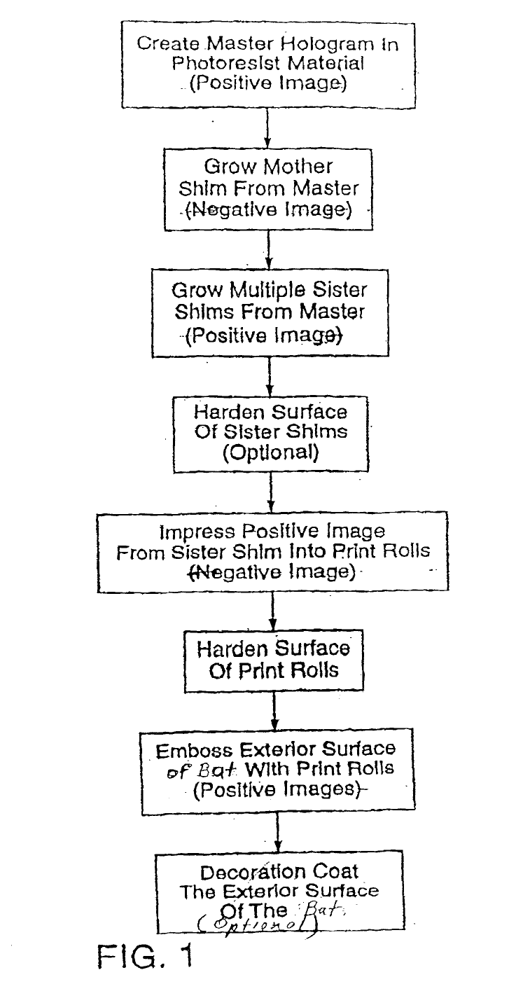

Referring to the drawings, FIG. 1 outlines a preferred process for engraving/embossing holograms in metal bats and other metal sporting and fitness products, and optionally applying a decorative or protective coating to the products either before or after they have been engraved/embossed. The first step of the process is to create a master hologram as is well known in the art. One common process (see U.S. Pat. No. 5,521,030 for example) is to apply a photosensitive coating (photoresist) to a substrate such as glass or metal and to etch the photoresist with two or more coherent beams of light (laser beams) to produce a surface relief pattern (hologram) with a depth corresponding to the intensity of the radiation at each point. The relief grooves or pits that are etched into the photoresist preferably have a maximum depth not greater than the thickness of the photoresist on the substrate. In a preferred embodiment of this invention, the photoresist preferably has a thickness of a least about 3 microns (120 microinches) in order to obtain relief grooves or pits in the hologram in the photoresist that are at least about 2 microns deep, and more preferably about 3 microns deep. The relieve grooves may have an aspect ratio of depth to width in a range of about 1:0.5 to 3:1. The master hologram that is produced in the photoresist material is fragile and relatively soft.

The image in the photoresist of the master hologram is a “positive” image. As used herein, a “positive” image means the same image as is desired in the final object. A “negative” image is the inverse of a positive image, like the image in a mirror in which letters/words/images or other directional-sensitive decorations or patterns are reversed. FIG. 1 shows the image in the master hologram as being a positive image, but it could also be created as a negative image in the sense of any letters/words or other directional-sensitive images. If the image in the master hologram is created as a negative image with letters/words reversed, then the number of image transfers from master hologram to the final object will be changed by adding or subtracting an odd number of transfers so the letters/words on the final object will be positive. If there are no letters/words in the image, then it may not matter whether the image on the final object is positive or negative.

The next step, which is also well known in the art, is to grow a metal shim or mother shim from the master hologram. This can be done by applying a conductive coating (for example, silver spray) over the photoresist and then immersing the photoresist, i.e., the master hologram, in a bath of metal salts such as nickel salts and electrolytically growing or depositing nickel on the master hologram to generate a negative image of the hologram in a nickel shim. The image on the shim is the inverse of the image on the master hologram in that the grooves in the master hologram produce ridges or peaks on the shim, and also the reverse of the image on the master hologram. The thickness of the metal (nickel) shim varies depending on several factors such as the growing time used. The height of the ridges or peaks on the shim is the same or close to the same depth as the grooves in the photoresist. After the nickel shim has grown to the desired thickness, it is peeled or stripped from the master hologram to expose the negative image in the surface of the mother shim.

The next step in the process is to create multiple shims from the mother shim. It is known in the art to produce 100 or more daughters of the mother shim. This is done by growing daughters of the mother shim (sister shims of each other) in a bath of metal salts in the same manner that the mother shim was grown on the master hologram as described above. In this way many sister shims are grown. A negative image on the mother shim becomes a positive image on each of the sister shims. It is important that the surfaces of the mother shim and the sister shims be as smooth as possible to avoid pressing any imperfections from such surfaces into the hologram images made from the shims. It is also important that the undersurface of the sister shims be smooth. Since the shims are relatively thin, small blemishes on the undersurface of the shims or on surfaces on which the shims are mounted can be transferred through the shims into the holograms produced by the shims. The opposite faces or surfaces of the shim should be parallel, and the shim should have a uniform thickness within a tolerance of less than about 0.005 inch from edge-to-edge across the width of the shim.

When the sister shims are grown from the mother, the image on each of the sister shims is the inverse of the image on the mother shim. Thus, ridges or peaks on the mother shim will be grooves or pits in the sister shims. The depth of such grooves or pits are desirably as close to the height of the ridges or peaks on the mother image, but may be considerably less, such as only about 50% of the height of the ridges or peaks, as a result of the transfer process.

Optionally, the sister shims are electroformed in a hardening bath to produce enhanced hardness and durability, and/or may have a hard surface coating applied to them. The use of a hardening bath is disclosed in U.S. Pat. No. 6,017,657. The nickel can also be hardened by ion implantation with nitrogen plasma. The hologram surface can be coated with a thin diamond-like carbon (DLC) coating or amorphous diamond coating (ADC) or diamond-like carbon films or carbon nitride coatings. The coatings or films may be formed on the surface of the shims by high temperature chemical vapor deposition (CVD) or enhanced cathodic-arc physical vapor deposition processes that create a high energy flux of carbon ions that are caused to be embedded in the surface of the shim. DLC coatings can also be applied by low temperature physical vapor deposition (PVD) such as cathodic arc deposition of the coating. The physical and mechanical properties of the shim substrate remain substantially unaffected by the coating process, but the coating on the surface has a hardness approaching that of natural diamond. The coating is tightly bonded to the shim substrate and is abrasion resistant. Due to the amorphous nature of the ADC, it requires no post-coat polishing. The coating is continuous and homogeneous and substantially exactly replicates the underlying surface so it does not noticeably degrade the topography of the hologram image. The Tetrabond® Division of Multi-Arc Inc. in Rockaway, N.J. applies TETRABOND® coatings or other similar coatings on a variety of products for various uses and also supplies equipment for applying such coatings.

It is known that ADC coatings or films may contain high levels of compressive stress. It is believed that the stress levels may be reduced by using a newly developed coating process that uses a pulsed laser on a graphite target at room temperature to produce a high percentage of diamond-like bonds. The coating so produced initially has a high stress level, but heating the coating reduces its stress while retaining its diamond-like properties. The resultant coating is reportedly extremely smooth and more stable than typical diamond films that contain hydrogen. It has been reported that Sandia National Laboratory has filed for a patent on this new process.

The ADC or DLC coating or film is preferably less than about 5000 angstroms thick in order to minimize masking or dulling of the hologram in the surface. ADC coatings may have hardness in a range of about 80-100 Gpa (giga pascal) (8,000-10,000 Vickers), be optically smooth and have a high adherence to the shim substrate. DLC coatings may have hardness in a range of about 10-50 Gpa (1,000-5,000 Vickers). The Gpa hardness measure is used by Multi-Arc Inc., whereas Vickers or Knoop Microhardness (KHN), which is a stress value measured in kg/mm² (kilograms per square millimeter), is used below as the measure of hardness of shims, metal rolls and cans. Rockwell hardness can also be used to measure surface hardness. One kg/mm² is the equivalent of one Newton/mm² in the meter-kilogram-second system. Hardness measurements depend on the nature and size of the indenters, and there are no generally accepted conversion factors from one unit of measurement to another.

The sister shims preferably have a surface hardness of approximately 550-600 kg/mm² (500-600 KHN), regardless of whether they have enhanced hardness or are hard coated as described above. It is important to provide sufficient surface hardness on the shims to effect a transfer of the hologram image into the surface of a print roll in the next step of the process. It is preferred that effective transfer of a hologram image from the shim to the print roll employ a hardness ratio of the two surfaces of at least about 2.5 to 1 and preferably at least about 2.7 to 1. This means that the surface from which the image is being transferred should be at least about 2.5 times, and preferably at least 4 to 5, harder than the surface into which the image is being impressed.

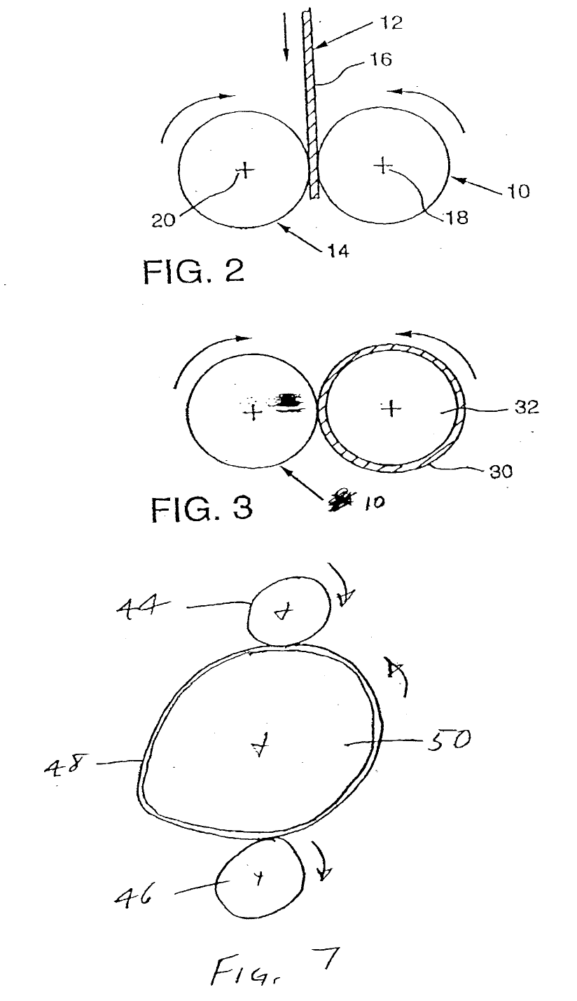

The next step in a preferred method of this invention is to transfer the positive image from a sister shim into the surface of a print roll or rolls. This is illustrated in FIG. 2. The support rolls are preferably polished aluminum, steel or other hard metal cylinders made from an aluminum alloy such as 6061, 7075 or other 6000 and 7000 series aluminum alloys, or steel alloys such as 4140, 1018, 1045 and mold steel alloys, and have surface hardnesses of about 110-125 kg/mm². Print rolls made of 2024 or 4045 aluminum alloys, or other lower yield strength aluminum alloys or other softer, lower strength metals, may also be suitable for some applications. However, print rolls made of higher yield strength alloys, such as 7075 aluminum alloy and 4140, 1018, 1045 and mold steel alloys, appear to be more robust and capable of more cycles of operation than rolls made of lower yield strength alloys. The print rolls may also be steel or other metal, with or without metalized coatings, such as metalized aluminum, on them.

The print rolls are preferably either acid or alkaline cleaned and then polished, buffed or bright dipped before the hologram is pressed into their surface. A variety of known mechanical (such as polishing with an orbital sander) and/or chemical processes may be used to provide a smooth, bright finish on the print rolls. A bright finish on the print rolls is beneficial for transfer of a hologram image to the print roll and perhaps even more beneficial for transfer of the image to the sporting or fitness products such as ball bats. Each print roll may have a diameter that is close or equal to the diameter of the bat or other products which are to be engraved by the print rolls, or may have a diameter that is larger or smaller than the diameter of the bats when multiple images are engraved on them. A typical aluminum bat may have a diameter of approximately 2.75 inches, and the print rolls in one embodiment of this invention have diameters of about 2.75 inches. Such roll diameter is also convenient for mounting the rolls in decoration apparatus as will be described.

It is also believed that the yield strength of the print roll substrate under the surface coating affects the quality of image transfer onto the surface of bats or other sporting products. If the underlying substrate metal in the print roll has a low yield strength, the metal may not provide sufficient support for the hard surface on the print roll under the pressures required to make the transfer. It is therefore believed that the high yield strength aluminum alloys such as 6000 and 7000 series alloys and certain steel alloys are beneficial to making a good image transfer. It is noted that in the use of such rolls to transfer images to thousands of bats, little or no spalling or flaking of the ADC coatings from the rolls has occurred or been observed.

Each print roll 10 (FIG. 2) may have a length approximately equal to the length or barrel portion of the bats to be embossed. A typical baseball bat may have a barrel of about 10.0-12.0 inches, so the print rolls are also preferably about 10.0-12.0 inches in length. The size of the print rolls can also be less than the length of the barrel, resulting in an image being transferred to only a portion of the barrel.

Each sister shim 12 having a hologram image on it is also preferably sized to correspond to the size of the surface area of bats to be embossed and the print rolls. For example, in one preferred embodiment, about 8.35 inches of bat barrel circumference and 12 inches of barrel length is embossed. Thus, the shim 12 is preferably about 8.35 inches by about 12 inches. However, the diameter and length of the print rolls is not critical to this invention.

As shown in FIG. 2, the shim 12 is pressed against the bright finished (mirror-like finish) print roll/cylinder 10 by a support roll 14. The image 16 on the shim 12 faces the print roll so the hologram image will be pressed into the surface of the print roll. The support roll 14 has a smooth surface to avoid impressing blemishes from the roll through the shim and into the print roll. As stated above, the surface hardness of the print rolls is preferably approximately 110-125 kg/mm² (or 110-125 KHN).

It is important that the axes 18 and 20 of the print roll 10 and support roll 14 are substantially parallel and that the rolls are as round in cross section as reasonably possible to make a good transfer of the hologram image into the print roll. The linear surfaces of the rolls 10, 14 from end to end should also be straight or preferably slightly crowned to make a good transfer of the image into the print roll. The rolls are rigidly mounted to minimize deflection in the rolls during the image transfer. The rolls are pressed against the shim as it moves between them under a linear pressure of about 1000-2200 pounds per linear inch of the contact surface between each roll and the shim. The rolls 10, 14 are rotated as shown by the arrows, and the shim 12 moves through the nip between the rolls. Care must be used to insure that the shim is properly aligned as it passes through the nip between the rolls and to prevent slippage between the shim and print roll.

Following transfer of the holographic image to the print rolls, the surfaces of the rolls are hardened. This can be done by ion implantation or by coating the rolls with ADC or DLC as described above with reference to the sister shims. Other coatings, as available, may be used to provide hard surfaces on the rolls, in place of ADC and DLC coatings. The ADC or DLC is also believed to be beneficial to reducing oxide or other scum build-up on the print rolls when they are used to microengrave bats or other sporting or fitness products as described below. The surfaces of the print rolls preferably have a minimum hardness of at least 545 to 600 kg/mm² (or 545-600 KHN) after they have been hardened. The surfaces of the print rolls should be at least 2.5 times, and preferably at least about 4 to 5 times, harder than the surface hardness of aluminum sports products to be decorated. Aluminum bats and other sports products have tensile yield strengths (TYS) of about 85 ksi and Knoop Microhardness or about 200. A surface hardness of at least about 500 kg/mm² (or 500 KHN) on the print rolls is required to make a good transfer of the image into the surface of the products. For softer products, the print rolls may have a lower surface hardness.

The next step in the method of this invention is to microengrave/emboss the exterior surface of bats or other products as shown in FIG. 3. An aluminum bat 30 is positioned on a mandrel 32 to support the barrel of the bat against the force of a print roll 10. Several different aluminum alloys are typically used in baseball bats, including 7046, C405, C55 and C805. C405, for example, has a tensile yield strength (TYS) of about 85 ksi and a KHN of about 200. As stated above, the print roll 10 should have a hardness of at least about 2.5 to 3 times the surface hardness of the bat. The print roll 10 is pressed against the surface of the bat as the mandrel and the print roll are rotated as indicated by the arrows in FIG. 3. As described above with respect to image transfer from a sister shim to a print roll, the axes of the mandrel and the print roll must be parallel and the linear surfaces from end-to-end of the mandrel and print roll must be as straight as reasonably possible or alternatively have a slight crown on the print roll. The pressure of the print roll against the bat surface is preferably about 3000 to 4000 pounds per linear inch of contact at the bat/print roll interface. The pressure must be sufficient to microengrave/emboss the holographic image from the print roll into the surface of the bat, but should not be so high as to significantly extrude metal in the wall of the bat between the print roll 10 and the mandrel 32. Extrusion of metal in the wall of the bat causes thinning of the wall and may deform the bat. However, a small amount of metal working and thinning of the wall is acceptable and usually occurs. Such metal working may result in slight changes in the circumference of the barrel of the bat and a slight increase in the strength of the bat in the area of the metal working. The print rolls may be heated slightly to improve transfer of the image into the surface of the bats. The bats or other sporting products are preferably at room temperature during transfer of the holographic image into the surface of the products.

Due to the high pressure required to transfer the holographic image from the print roll to the sporting product and the fact that the mandrel 32 is necessarily a cantilever on which the bat is positioned, some deflection of the mandrel is difficult to avoid. Deflection of the mandrel may result in non-uniform pressure of the print roll 10 against the bat 30 from one end of the bat to the other, and may produce unsatisfactory transfer of the image. Accordingly, supplemental means may be desirable to equalize the transfer pressure along the length of the bat. Such supplemental means may comprise applying a greater pressure of the print roll against the bat at the unsupported end of the mandrel, angling the axis of the mandrel toward the axis of the print roll so the mandrel is “toed-in” from the base of the mandrel to the unsupported end of the mandrel, or by providing a backup roll or an outboard bearing support for the mandrel/can or the print cylinder if this can be done without significantly degrading the quality of the image on the bat. Different pressure profiles on the print cylinder/roll 10 may also be used to reduce the effects of deflection of the mandrel 32 and/or print roll during transfer of the image. For example, the print roll 14 may have a slightly larger diameter mid-length (crown profile) or a tapered profile with a larger diameter at its outer end than at its base to reduce the effects of deflection.

For high volume production of aluminum bats and other hard metal products, it may be beneficial to apply a lubricant on the surface of the print rolls or the metal products during transfer of the image from the print roll to the product. The lubricant may be applied to roll 10 shown in FIG. 3 or to the bats 30 before the print roll/cylinder is pressed against the bats. The lubricant may help reduce the production of metal fines or other debris during transfer of the image to the bat and may also help remove any metal fines or debris which are produced from the surface of the die. Metal fines and/or other debris that may accumulate on the surface of the die may interfere with transfer of the image to the bats, particularly if the same die is used to decorate many thousands of bats. The fines and debris tend to blind the dies or make them less effective in impressing the holographic image into the surface of the bats or other articles. In a preferred embodiment, the lubricant may be sprayed intermittently on the print roll 10, and a cleaning wheel, not shown, may be employed to remove fines from the roll.

Lubricant may be applied to the print roll 10 (FIGS. 3 and 4) by a backup flat bar, not shown, covered with a soft fabric. The bar would vibrate in an orbital trajectory that is parallel to the interface between the bar and the print cylinder as the bar is pressed against the print cylinder. Lubricant is applied to the fabric and transferred from the fabric to the print cylinder while debris is removed by the fabric. Lubricant may also be applied to the print roll by spraying the roll with lubricant, such as a fine mist of lubricant.

It is believed that a variety of lubricants or boundary additives to lubricants may be used on the die or bats including such things as fatty acids, fatty alcohols and esters, including oleic acid, stearic acid, methyl stearate and butyl stearate. The quantity of lubricant should be controlled to avoid possible detrimental effects on the bats. For example, excessive quantities of some lubricants may cause dulling or cloudiness on the surface of the bats. It is therefore desirable to carefully meter the lubricant onto the print roll and/or bats, and or ineffective transfer of the holographic image from the tool to the bat. One way of doing this is to use a backup flat bar to which lubricant is supplied to be transferred to the print roll and bats, as is explained above. The position of the backup flat bar can be precisely controlled to limit the amount of lubricant that is carried through the nip between the backup flat bar and the print roll. Metering of lubricant between two rolls in such a manner is well known in the art.

Ball bats and other sporting and fitness products, which are decorated and/or authenticated in accordance with this invention, are preferably also decorated and/or colored with a powder coating or by anodizing the surfaces of the products. Both such processes use silk screening as the primary method for decorating/coloring the products. Such decorating/coloring may be done either before of after the sporting product has been microengraved with a holographic image in accordance with this invention.

FIG. 4 shows laboratory apparatus 22 for transferring holograms from a print roll to the barrel portion of ball bats. The apparatus 22 comprises a frame 24 having a mandrel 32 and a print cylinder 10 mounted in it for rotation on parallel axes. The mandrel 32 is mounted with its tapered end 26 extending through the frame 24 so the tubular barrel 34 of bat 30 can be slid over the tapered end 26 and onto the body portion of the mandrel. The base end of mandrel 32 is mounted on bearings in the frame 24 so the mandrel can rotate freely on its longitudinal axis. The print cylinder 10 is mounted in the frame for rotation on its longitudinal axis by a drive motor 28 and drive shaft 38. The print cylinder 10 has the holographic image in its outer surface as is described above. In the operation of the apparatus 22, the barrel 34 of the bat 30 is slid into position over the mandrel 32, the mandrel and print cylinder 10 are moved against each other, by means not shown, with the thin wall of the barrel 34 therebetween, and the print cylinder is rotated up to about 360 degrees on its longitudinal axis. Such rotation of the print cylinder against the bat causes the bat and the mandrel to rotate also. The pressure of the print cylinder 10 against the bat on the mandrel should produce at least about 1500 to 2000 lbs/in² (gauge pressure) to microengrave the holographic image into the surface of the bat. Upon completion of the transfer of the image, the rotation of the print cylinder 10 is stopped and the print cylinder and mandrel 32 are moved apart so the bat 30 can be removed from the mandrel.

It is noted that the combination of a holographic image and decorative coatings on a bat produces an extremely attractive bat. The decorative coating may be applied only to the surface of the bat which doesn't include the hologram, or may also be applied over all or part of the hologram. The hologram and decorative coating interact to produce an appearance not previously possible in the manufacture of bats.

### EXAMPLES

FIG. 5 shows one example of aluminum ball bat 30 that had been decorated by the method of this invention having a hologram comprising pictures of bats, balls and stars engraved in or embossed on its surface. The light which reflects off the hologram produces varying looks or images as the bat is moved in the light. The hologram image has been transferred to the barrel portion 34 only of the bat, which is cylindrical. However, it is believed that this invention may also be used to transfer holographic images to the tapered portion 36 of the bat.

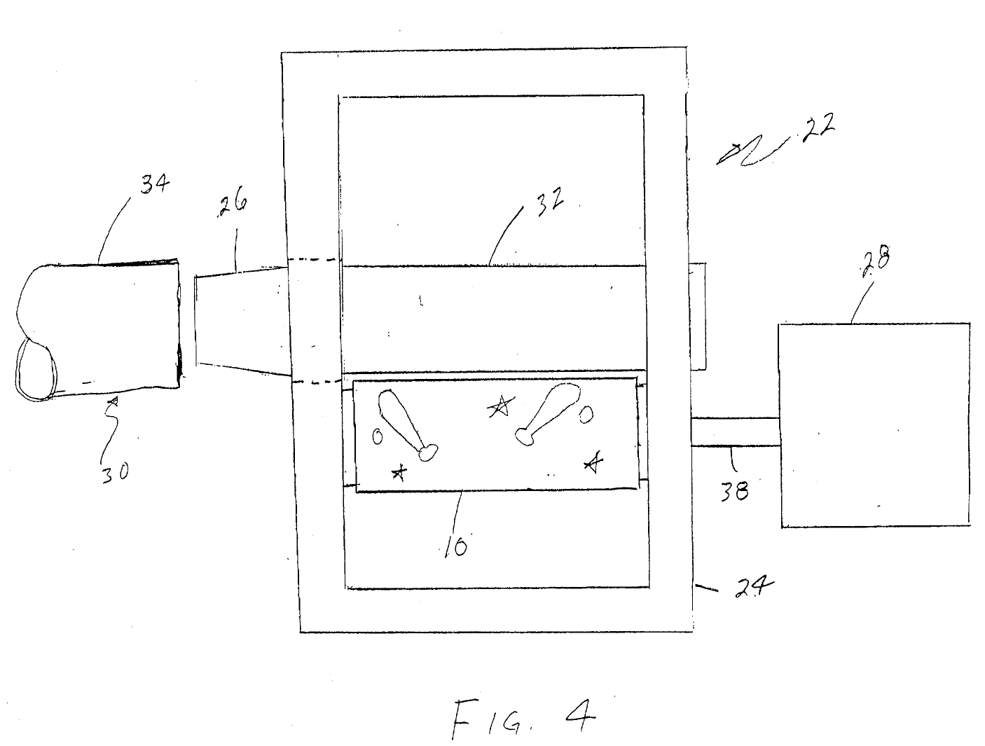

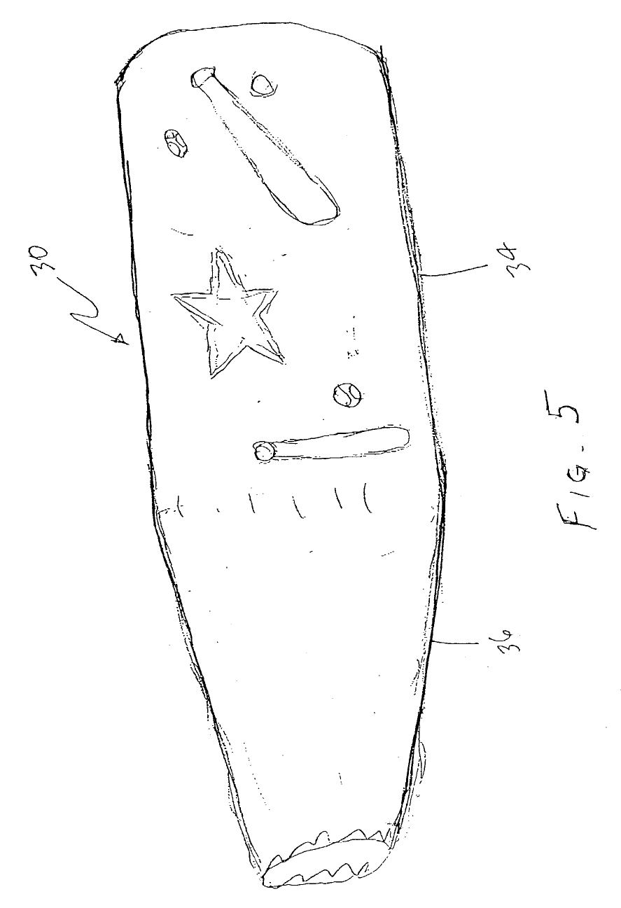

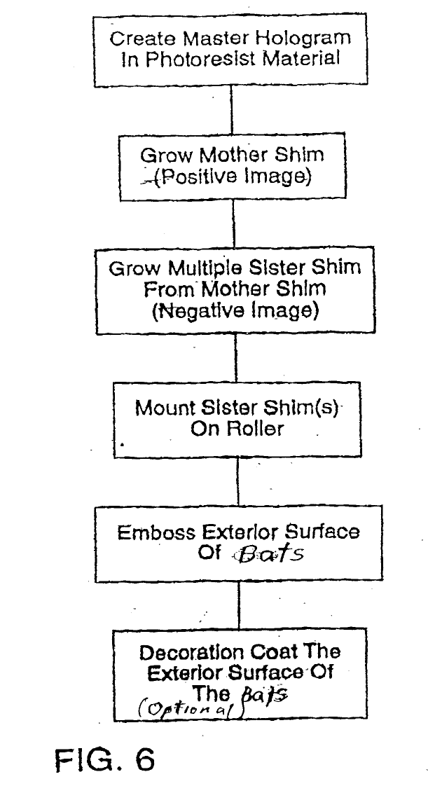

FIG. 6 is a flow diagram of an alternative mode for practicing the invention. In this mode the sister shims are mounted directly on a roller which is used to engrave/emboss the exterior surface of ball bats. In this way it is not necessary to first transfer the image from the sister shim to a print roll as in the method of FIG. 1. The sister shims that are mounted on the roller are preferably arcuate in cross-section and fit against the arcuate outer surface of the roller and secured thereto.

The shims in the method of FIG. 6 have negative holographic images on them and press a positive image in the exterior surface of bats. The image in the photoresist material comprises grooves/pits, the image on the mother shim comprises ridges/peaks, the images on the sister shims comprise grooves/pits, and the images in the surface of the bats comprise ridges/peaks. It is important to the method of FIG. 6 that the shims have a surface hardness of at least about 500 to 650 kg/mm² (or 500-650 KHN) in order to effectively press a hologram into the surface of aluminum bats having surface hardness of about 150 to 200 kg/mm² (or 150-200 KHN). The surface of the shims may be optionally hardened with DLC or ADC as is described above with respect to the method of FIG. 1.

In one alternative embodiment of the invention, a print roll is used that has a holographic image on only a portion of the circumference of the roll, and has a blank or smooth surface on the remainder of the circumference of the roll, and has a blank or smooth surface on the remainder of the circumference of the roll. The roll preferably has a larger diameter than the bat, and the arc length of the roll having the holographic image on it is approximately the same as the circumference of the bat so the full circumference of the bat will be decorated by the print roll. In the operation of such a print roll, the smooth surface of the roll is first moved against the exterior surface of the bat, followed by rotation of the bat and print roll against one another until the circumference of the bat has been decorated. The print roll and bat on its mandrel then separate so the decorated bat may be removed from the mandrel. An advantage of this alternative embodiment is that the initial force or impact of the print roll against the bat will not cause excessive digging-in or non-uniform engraving of the surface of the bat by the holographic image on the print cylinder. Instead, the blank/smooth surface of the print cylinder absorbs the impact of bringing the print roll into pressure contact with the bat. This mode of operation also helps to prolong the life of the print cylinder by reducing degradation of the image on the print roll from impact of the roll against the bat. It may also brighten the surface of the bat as the smooth surface of the print roll is rolled against the bat.

Another alternative embodiment of this invention is shown in FIG. 7 in which two print rolls/cylinders 44, 46 are rolled against a bat on a mandrel 50. The print rolls 44, 46 may be smaller in diameter than the bat 48, and each roll decorates one-half of the circumference of the bat. This alternative helps reduce deflection of the mandrel 50 because the print rolls support opposite sides of the mandrel 50. The print rolls 44, 46 may also have blank portions on their surfaces for making initial contact with the surface of the bat as is discussed above.

In another embodiment of this invention, print rolls are produced and used that have grooves or pits in their surface instead of ridges/peaks on the surface. One of the problems in producing holographic images on hard metal objects, such as bats and other sporting products is producing consistently high quality images in high volume production. Achieving this is greatly facilitated by the use of high quality print rolls. It has been found that transfer of holographic images from a photoresist coated plate, to a mother shim, to sister shims and print rolls results in progressively shallower grooves/pits and ridges/peaks in each transfer. For example, transfer of an image from a sister shim to a print roll may be only about 50% effective. This means the ridges on the print roll will be only about 50% as high as the depth of the grooves in the sister shim. The transfer from the print roll to the hard metal bats or other objects may also be only about 50% effective. It is especially desirable to improve the transfer of the holographic image from a shim to a print roll. Accordingly, in one alternative invention, a shim having ridges/peaks, instead of grooves, on the surface is used to transfer the holographic image to the print roll. This produces an improved print roll for use in decorating metal objects in accordance with this invention.

Whereas particular embodiments of this invention have been described for purposes of illustration, it will be evident to those skilled in the art that numerous variations in details may be made without departing from the invention as covered by the appended claims. For example, the method of this invention can be used to emboss/engrave holograms on a variety of products such as sports rackets, tubes for bicycle frames and other tubular articles of manufacture. Some such products may have surface hardnesses in a range of about 100 to 200 kg/mm² (or 100-200 KHN) It is also possible to modify this invention by embossing sporting products directly from the shims instead of first transferring the hologram to a print roll. In that alternative, a bat or other article is mounted on a mandrel and rotated as a shim having a hologram on it is pressed against the bat by a supporting roll in a manner similar to that shown in FIG. 2. The shim could also be arcuate in shape to conform to the arcuate surface of the support roll. Such an arcuate shaped shim may be attached to and be rotated with the support roll.

Shims used with this invention may also be prestressed or alternatively stress relieved to reduce squirming or movement of the edges of the shims during transfer of images to a print roll or other objects. The edges of the shims may also be supported by a backup roll to reduce such squirming of the edges.

Print rolls used in this invention can also vary in diameter and may be smaller, the same as, or larger in diameter than the articles being embossed. The ADC or DLC coatings on print rolls and/or shims may also vary in thickness down to about 1,000 angstroms although they are preferably about 2,000-3,000 angstroms thick. The products that may be decorated in accordance with this invention may also have a thin, clear coating of polymer such as polyester on them, and the holographic image may be transferred to such coating that is similar to image transfer to credit cards or the like, although with less clarity of the image as compared with transfer of images into bare metal. Although the invention has been described in terms of forming images on ball bats, the invention is not intended to be so limited. It is contemplated that the invention will be especially useful for tubular sporting products of all kinds such as lacrosse sticks, hockey sticks, polo sticks, field hockey sticks, ice hockey sticks, pool cues, arrows, gun scopes, wind surfing frames, sail board booms, inline skate components, wheelchairs, golf club shafts, motorcycle and bicycle frames and components (handlebars, seat posts, suspension systems), ski poles, javelins, bowling pins and the like. Other modifications to the invention falling within the scope of the appended claims will be apparent to those skilled in the art.

We claim:

1. A method of applying a holographic image to the surface of a tubular article made of hard temper metal comprising:
providing a shim having a holographic pattern in its surface,
transferring said pattern from said shim to a die having a surface hardness of at least about 110-125 kg/mm² (or 110-125 KHN),
hardening said surface of the die by a process selected from ion implantation and coating the surface of the shim to increase surface hardness to a minimum value of about 545 kg/mm² (or 545 KHN),
providing a tubular metal article to be impressed with said holographic image, said article having a surface hardness of at least about 50 kg/mm², and
pressing said die against a surface on said metal article to transfer said holographic image into a surface on said metal article.

2. A method as set forth in claim 1 in which said coating of the surface of the shim is with diamond-like carbon, amorphous diamond coating or carbon nitride.

3. A method as set forth in claim 1 in which said die is applied seriatim against the surface of a succession of said metal articles.

4. A method as set forth in claim 1 in which lubricant is sprayed on the surface of at least one of said die and said article to reduce or eliminate buildup of debris on the surface of said die.

5. A method as set forth in claim 1 in which said die is a print cylinder made of hard temper metal.

6. A method as set forth in claim 1 in which said article is a hard temper aluminum alloy ball bat.

7. A method as set forth in claim 1 in which said article is a hard temper aluminum alloy tube for a bicycle frame.

8. A method for producing a die for use in impressing a holographic image many times into numerous tubular hard metal articles comprising:
providing a photoresist coated plate,
etching a holographic pattern in the photoresist,
growing a mother shim with said pattern in it from said plate,
transferring said pattern directly or indirectly from said mother shim to a metal die, and
coating at least a portion of said die bearing said holographic image with a diamond-like coating.

9. A method as set forth in claim 8 in which said coating is an amorphous diamond-like coating.

10. A method as set forth in claim 8 in which said holographic pattern is etched in said photoresist coating to a depth of about 2-3 microns.

11. A method as set forth in claim 8 in which said coating has a thickness less than about 5000 angstroms and a hardness of at least about 80 Gpa (or >1000 KHN).

12. A method as set forth in claim 8 in which said die is a cylinder made of hard metal and said holographic image is formed in the surface of said metal cylinder.

13. A method as set forth in claim 8 in which said pattern in said metal die comprises pits in the surface of the die.

14. A method as set forth in claim 8 in which said pattern in said mother shim is transferred to at least one sister shim and from said sister shim to said metal die.

15. A method of applying a holographic image to the surface of tubular articles made of hard temper aluminum comprising:
providing at least one cylindrical print cylinder having a holographic image in its surface around at least a portion of the circumference of the print cylinder and having a hardness of at least about 400 to 500 KHN,
providing a hard temper aluminum tubular article having a longitudinal axis parallel with the longitudinal axis of said at least print cylinder,
moving at least one of said at least one print cylinder and said tubular article toward the other to press the surface on the print cylinder against said tubular article under substantial interfacial pressure, and
rotating at least one of said tubular article and said at least one print cylinder on its longitudinal axis while maintaining said substantial interfacial pressure to transfer said image from said print cylinder to the surface of said article.

16. A method as set forth in claim 15 which includes pressing two of said print cylinders against said tubular article on substantially opposite sides of the article.

17. A method as set forth in claim 16 in which said two print cylinders each have a portion of a holographic image that is transferred to said tubular article and each cylinder rotates against a separate portion of the article.

18. A method as set forth in claim 15 in which said print cylinder or tubular article is mounted as a cantilever and a bearing support is provided for the end of said cantilever to reduce deflection of the cantilever.

19. A method as set forth in claim 15 in which said holographic image in said print cylinder comprises pits/grooves in the surface of the cylinder.

20. A method as set forth in claim 15 in which the tubular article is an aluminum ball bat.
